(19) United States
(12) Patent Application Publication
(10) Pub. No.: US 2015/0101649 A1
(43) Pub. Date: Apr. 16, 2015

(54) HIGH UTILIZATION PHOTO-VOLTAIC DEVICE

(71) Applicant: Dow Global Technologies LLC, Midland, MI (US)

(72) Inventors: Hua Liu, Midland, MI (US); Jie Feng, Midland, MI (US); Leonardo Lopez, Midland, MI (US); Rebekah Feist, Midland, MI (US); Keith Kauffmann, Ypsilanti, MI (US)

(21) Appl. No.: 14/402,350

(22) PCT Filed: May 29, 2013
(86) PCT No.: PCT/US2013/043104

§ 371 Date: Nov. 20, 2014

Related U.S. Application Data
(60) Provisional application No. 61/653,964, filed on May 31, 2012.

(51) Int. Cl. H01L 31/02; H01L 31/0203; H01L 31/0443

(52) U.S. Cl. CPC H01L 31/0201; H01L 31/0443; H01L 31/0203
USPC 136/244; 438/80

(57) ABSTRACT

An article of manufacture includes a first and second PV cell layer, where the first and second PV cell layers are at least partially displaced from each other and define a continuous optical coverage area throughout a solar active area. The article provides for enhanced utilization of the active solar area.

### FIELD

The present invention relates to improved photo-voltaic devices, and more particularly but not exclusively relates to photo-voltaic devices having an enhanced utilization of the active solar area.

### INTRODUCTION

Presently known photo-voltaic (PV) devices include an active solar area which is the portion of the PV device where photons are received and converted to electrically available energy. In many devices there is a non-utilized fraction of the active solar area that is reserved for, and/or areas that are screened by, electrical connection assembly elements such as a bus bar and/or conductive elements that carry electrical current within and between cells of the PV device. Certain PV materials require spacing around or between cells to prevent shunt currents, to provide for heat transfer, due to cell shape and size availability constraints, and/or for other reasons. Accordingly, certain types of presently known PV devices cannot utilize a significant fraction of the active solar area for the capture of photons. In certain applications, for example PV devices integrated into building products where the application surface area is predetermined, unit capture of solar energy by area is a priority and can affect whether an installation is economically viable.

Among the literature that can pertain to this technology include the following documents: U.S. Pat. No. 6,121,541; U.S. Pat. No. 6,368,892, US 2005/0056312(A1); U.S. Pat. No. 5,261,969; U.S. Pat. No. 4,795,501; U.S. Pat. No. 5,008,579; US 2011/0220175(A1); US 2011/0220177(A1); US 2011/0100436; U.S. application Ser. Nos. 12/989,743 and 13/499,483.

### SUMMARY

The present disclosure in one aspect includes an article of manufacture having a transparent front sheet defining a solar active area. The front sheet is structurally coupled to a back sheet, and the front sheet and back sheet include a PV device positioned between them. The PV device includes a first PV cell layer having a first PV active material and a second PV cell layer having a second PV active material. The first and second PV cell layers are at least partially displaced and together define a continuous optical coverage area throughout the PV active area.

Additional or alternative aspects of the disclosure may be further characterized by any one or more of the following features: the first PV active material and the second PV active material each being distinct materials; the first PV cell layer and the second PV cell layer being electrically isolated layers within the frame of the solar active area; the continuous optical coverage being an area where at least one of the first and second PV active materials are directly exposed over at least 85% of the exposed facial area of the solar active area; the first PV cell layer and the second PV cell layer each having a distinct bypass diode; the article further including an external circuit coupling, where the external circuit coupling is electrically coupled to the first and second PV cell layers in a series, parallel, or series-parallel configuration; the article further including a first external circuit coupling electrically coupled to the first PV cell layer, and a second external coupling electrically coupled to the second PV cell layer; the first PV cell layer including a first number of cells having an aspect ratio with a major axis positioned in a first direction and the second PV cell layer including a second number of cells having an aspect ratio with a major axis positioned in a second direction that is divergent from the first direction, which may be perpendicular to the first direction; the second PV cell layer including a frame shaped to the solar active area less an accommodation for the first PV cell layer; the first PV active material including crystalline silica (c-Si) and the second PV active material including copper-indium-gallium-selenide (CIGS); the second PV cell layer shaped to the solar active area and being positioned vertically below the first PV cell layer; and/or a vertically upper one of the first and second PV cell layers is positioned to optically screen an electrical connection assembly of the vertically lower one of the first and second PV cell layers.

An additional or alternative aspect of the present disclosure is a method including forming a PV device, where the forming includes providing a first PV cell layer having a first PV active material and a second PV cell layer having a second PV active material, and positioning the second PV cell layer at least partially displaced from the first PV cell layer. The method further includes interpreting an external circuit description, electrically coupling the first PV cell layer and the second PV cell layer in an electrical configuration selected in response to the external circuit description, providing a transparent front sheet and a back sheet, positioning the PV device between the front sheet and the back sheet, such that the front sheet defines a solar active area and the first PV cell layer and the second PV cell layer define a continuous optical coverage area throughout the solar active area, and structurally coupling the front sheet to the back sheet.

Additional or alternative aspects of the disclosure may be further characterized by one or more of the following features: electrically coupling the PV cell layers in series to an external circuit coupling, electrically coupling the PV cell layers in parallel to an external circuit coupling, and/or electrically coupling the first PV cell layer to a first external circuit coupling and electrically coupling the second PV cell layer to a second external circuit coupling.

### BRIEF DESCRIPTION OF THE DRAWINGS

FIG. 1 is a schematic diagram of a previously known PV device.

FIG. 2 is a schematic diagram of an article of manufacture including a PV device.

FIG. 3 is a cutaway view of the article of manufacture depicted in FIG. 2.

FIG. 4 is a schematic diagram of a first and second PV cell layer.

FIG. 5 is a cutaway view of the first and second PV cell layers depicted in FIG. 4.

FIG. 6 is a schematic illustration of a first and second PV cell layer, each including a distinct bypass diode.

FIG. 7 is a schematic illustration of an article of manufacture including a first and second PV cell layer, each coupled to separate external circuit couplings.

FIG. 8 is a schematic illustration of an article of manufacture including a first and second PV cell layer, each coupled to an external circuit coupling.

FIG. 9 is a schematic illustration of an embodiment of a first and second PV cell layer, depicted in an exploded view.

FIG. 10 is a schematic illustration of the embodiment of FIG. 9, depicted in an assembled view.

### DETAILED DESCRIPTION

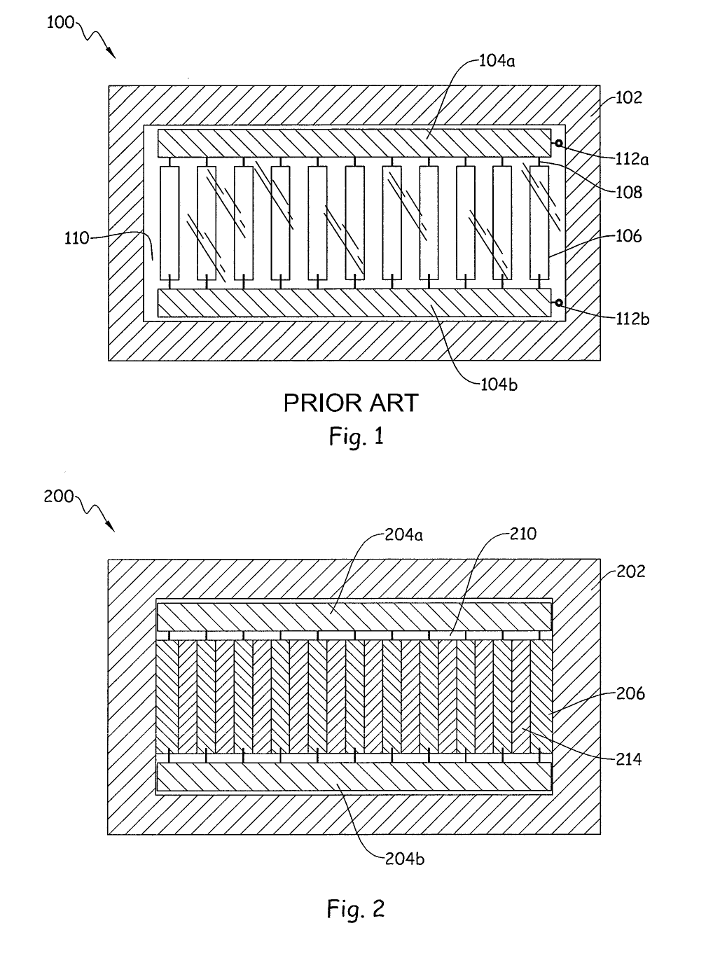

Referencing FIG. 1, a previously known PV device 100 is schematically depicted. The PV device 100 in the example is a building integrated cell, for example placed on a roofing shingle or other building material unit. The PV device 100 includes a substrate 102, a number of photo-voltaic (PV) cells 106, and electrical connections 108 to a first bus 104a and a second bus 104b. The PV device 100 further includes couplings 112a, 112b to an external circuit. The PV device 100 includes a transparent cover 110, for example a glass cover, allowing light to reach the PV cells 106 and providing protection to the PV cells 106. It can be seen in FIG. 1 that the busses 104a, 104b and the spacing between the PV cells 106 compete for space within the frame of the transparent cover 110, reducing the amount of light incident to an PV cell for a given size and position of the PV device 100 and transparent cover 110.

FIG. 2 is a schematic diagram of an article of manufacture 200 including a PV device. The article 200 may be a PV device integrated with a building material unit, for example a roofing shingle, a siding panel, a structure designed to fit in place of a number of building units, or other product designed for building integration. The article 200 includes a substrate 202 surrounding a transparent front sheet 210. The transparent front sheet 210 defines a solar active area. The transparent front sheet 210 includes any material known in the art, including at least glass and plastic materials. Transparent, as utilized herein, should be understood broadly. The transparent front sheet 210 is transparent to the appropriate light frequencies for the PV cells of the PV cell layers 206, 214, which may include all or portions of the visible light spectrum, and may alternatively or additionally include portions of the light spectrum above or below the visible frequencies. It is further contemplated that two or more sheet elements may be provided to cooperate together to form a transparent front sheet 210. The transparent front sheet 210 participates in providing impact protection and environmental protection for the PV device. In certain additional or alternative embodiments, the transparent front sheet 210 may provide one or more additional functions, for example including an enhanced light capturing feature such as an anti-reflective coating, a lensing structure, and/or a configuration providing for total internal reflection (TIR) of otherwise reflected light.

The article 200 further includes a first PV cell layer 206. In the example of FIG. 2, a first one of a number of PV cells including a photovoltaically active (PV active) material is referenced 206 to avoid cluttering the drawing. Each of the members of the first PV layer 206, alternating within the solar active area under the transparent front sheet 210, is similarly one of the cells of the first PV cell layer 206. A second one of a number of PV cells 214 is referenced 214 to avoid cluttering the drawing. Each of the members of the second PV cell layer 214, alternating within the solar active area under the transparent front sheet 210, is similarly one of the cells of the second PV cell layer 214. The depicted arrangement is illustrative and non-limiting. The depicted cells are divided in the left-right direction of FIG. 2, but may additionally or alternatively be divided in the up-down direction, and/or may be of varying shapes and/or positions. In certain embodiments, more than two PV cell layers (not shown) may be provided. While the first PV cell layer 206 and the second PV cell layer 214 are illustrated as having cells aligned edge-to-edge, in certain embodiments there may be some overlap of the layers 206, 214.

The first PV cell layer 206 is at least partially displaced from the second PV cell layer 214. At least partially displaced in the present description indicates that, relative to the exposed facial area of the solar active area, the super-set of the coverage by the first PV cell layer 206 and the second PV cell layer 214 includes at least some area that is not covered by the first PV cell layer 206 and some area that is not covered by the second PV cell layer 214. The PV cell layers 206, 214 may cover mutually exclusive areas, or may have some areas of overlap. Where more than two PV cell layers are provided, any two of the PV cell layers are at least partially displaced.

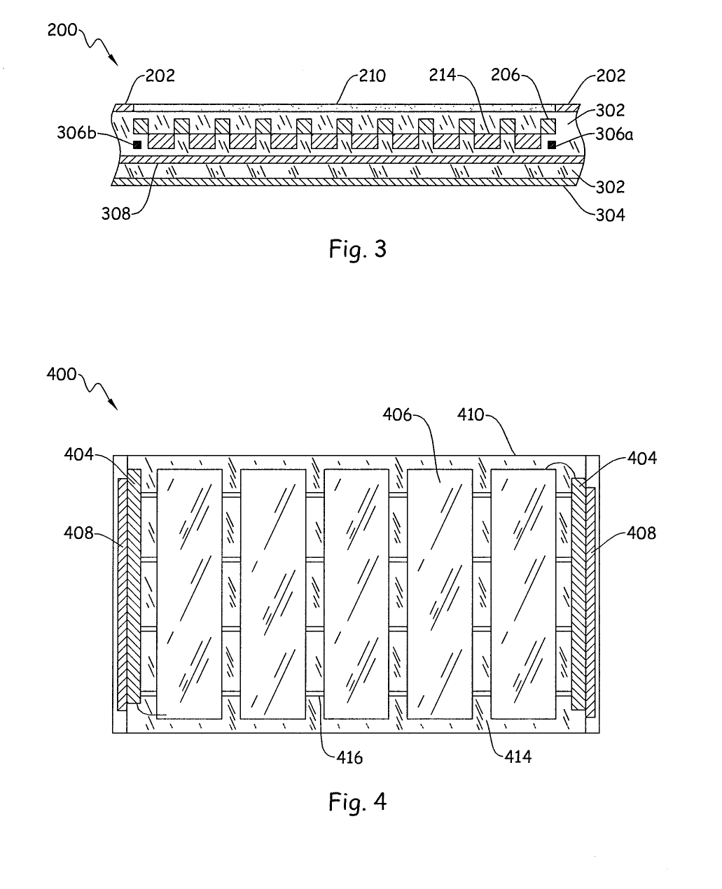

The article 200 further includes a first bus 204a and a second bus 204b electrically coupled to the first PV cell layer 206. The article 200 depicts the busses 204a, 204b electrically coupled to the first PV cell layer 206 in a parallel configuration as an illustration only. In certain embodiments, the first bus 204a and the second bus 204b are smaller than an ordinary bus 104a, 104b due to the total surface area of the first PV cell layer 206 being smaller than a total surface area of PV cells in a single layer device, such as PV cells 106 in the previously known PV device 100, and accordingly the first bus 204a and second bus 204b can be sized to accommodate a lower current level. In certain embodiments, the busses 204a, 204b may be positioned under the substrate 202 or otherwise outside of the transparent front sheet 210. Referencing FIG. 3, a third bus 306a and fourth bus 306b are depicted. The third bus 306a and the fourth bus 306b are electrically coupled to the second PV cell layer 214. The electrical connections to the busses 306a, 306b are a mechanical step for one of skill in the art having the benefit of the disclosure herein, and are not shown to promote clarity in the depiction of FIG. 3. The busses 306a, 306b may be electrically connected to the second PV cell layer 214 in a series, parallel, or combinations of parallel and series configurations.

In the example of FIG. 3, the first PV cell layer 206 is vertically higher than the second PV cell layer 214. Vertically higher, as used in the present disclosure, indicates a feature that is closer to the transparent front sheet 210 relative to another feature. The installed article 200 may have any orientation, for example between a shallow roof, wherein the article 200 is installed horizontally or nearly horizontally, and a wall installation wherein the article 200 is installed vertically. Accordingly, vertically higher, as utilized herein, is not related to the orientation of the article 200 as installed and/or during use. The vertically higher one of the first PV cell layer 206 and the second PV cell layer 214 is positioned to optically screen an electrical connection assembly of the vertically lower one of the first PV cell layer 206 and the second PV cell layer 214. An electrical connection assembly includes any electrical connection devices associated with a PV cell layer, including busses, conductive elements, and/or connections to any external circuits or external circuit access devices, and additionally or alternatively includes any portions thereof. In the example of FIG. 3, the busses 306a and 306b for the vertically lower second PV cell layer 214 are optically screened by the vertically higher first PV cell layer 206.

The first and second PV cell layers 206, 214 are depicted as being offset vertically by the width of one layer. Additionally or alternatively, the first and second PV cell layers 206, 214 may be in the same plane, partially offset but sharing some vertical extent, and/or offset by a greater amount than a single layer width. The first and second PV cell layers 206, 214 remain electrically isolated, except where electrical connection is intended, for example when the first and second PV cell layers 206, 214 are electrically coupled in series to an external circuit. Electrical isolation between the first and second PV cell layers 206, 214 may be maintained through insulating encapsulation materials, positioning of dielectric materials, and/or through any other isolation technique understood in the art.

The article 200 provides a reduced optical footprint of the exposed busses 204a, 204b, and provides for some of the total bus area to be optically screened, e.g. with the busses 306a, 306b. Additionally, the gap area between cells experienced by a single layer is reduced in the article 200. Accordingly, a higher utilization of the solar active area defined within the transparent front sheet 210 is achieved. In certain embodiments, a utilization of over 85% of the solar active area is achieved. In certain other embodiments, a utilization of lower than 85% is achieved. In certain embodiments, higher utilization rates are achievable including all values between at least 86% and at least 99%, inclusive. It is estimated that utilization of the solar active area, utilizing one or more of the features described herein, can approach 100% utilization. Utilization of the solar active area, as used in the present disclosure, includes either one of the PV materials from the first PV cell layer 206 or the second PV cell layer 214 being directly exposed within the exposed facial area of the solar active area. Direct exposure indicates that, other than transparent materials, a photon entering the transparent front sheet 210 within the solar active area at a normal angle first encounters a PV material from either the first PV cell layer 206 or the second PV cell layer 214. Accordingly, where 95% of the exposed facial area of the solar active area within the transparent front sheet 210 includes the first PV cell layer 206 or the second PV cell layer 214 as the first non-transparent material encountered, utilization of the solar active area is 95%.

The article 200 is depicted as a laminated building integrated PV device. A back sheet 304 is shown, which may be any material understood in the art, and is a support layer in the example article 200. In certain embodiments, the back sheet 304 provides puncture protection, e.g. from protruding nails on a roof surface. An encapsulant layer 302 is shown, in the example surrounding the PV cell layers 206, 214, and attaching the transparent front sheet 210 and the substrate 202 as well as the back sheet 304 illustrated as a lower support layer. Example and non-limiting encapsulant materials include a poly-olefin, an ethyl-vinyl-acetate, and/or a polymeric insulating material. The example article 200 further includes a barrier layer 308 between the backsheet 304 and the PV device. The barrier layer 308 is optional, and may provide protection from humidity, environmental intrusion, electrical insulation, etc. The PV device herein includes at least the first and second PV cell layers 206, 214. The transparent front sheet 210 and the back sheet 304 are structurally coupled, for example by adhesives holding laminated layers together, by the encapsulant, and/or by an attaching method occurring outside of the frame of the transparent front sheet 210. The back sheet 304, in certain embodiments, may be integral with the substrate 202 or a portion of the substrate 202. The back sheet 304, in certain embodiments, includes two or more layers of materials to provide the desired properties of the article 200.

The first PV cell layer 206 and the second PV cell layer 214 may be made of the same or distinct PV materials. Example and non-limiting PV materials include copper chalcogenide type cells (e.g. copper indium gallium selenides, copper indium selenides, copper indium gallium sulfides, copper indium sulfides, copper indium gallium selenides sulfides, etc.), amorphous silicon cells, crystalline silicon cells, thin-film III-V cells, thin-film II-VI cells, organic photovoltaics, nanoparticle photo-voltaics, dye sensitized solar cells, and/or combinations of the described materials. In certain embodiments, one of the PV cell layers 206, 214 is provided as a PV material deposited on the interior side of the transparent front sheet 210. An example embodiment includes the first PV cell layer 206 being c-Si and the second PV cell layer 214 being CIGS. In certain embodiments, the second PV cell layer 214 is CIGS deposited on glass, microglass, stainless steel, a transparent substrate, a non-transparent substrate, an organic substrate, and/or an inorganic substrate.

Referencing FIG. 4, an alternate embodiment of an apparatus 400 including a PV device having a first PV cell layer 406 and a second PV cell layer 414 is depicted. The depiction in FIG. 4 is simplified to enhance clarity. The solar active area 410 is illustrated, and the first PV cell layer 406 and the second PV cell layer 414 define a continuous optical coverage area throughout the solar active area. It can be seen in FIG. 4 that gaps 416 occur that are gaps between both the first PV cell layer 406 and the second PV cell layer 414. The optical coverage of the apparatus 400 is nevertheless continuous because coverage between cells of a cell layer 406, 414 are connected by coverage from cells of a differing layer. Without limitation and in certain embodiments, incidental gaps caused by features such as electrical connecting wires, insulation materials and/or a dielectric to prevent a shunt current or short circuit, and/or scratches, markings, or other features on the transparent front sheet 210 causing an incidental and/or temporary gap, are not breaks in optical coverage for the purposes of continuous coverage. Gaps extending the entire width or length of the solar active area 410, and having a significant extent such as, but not limited to, a gap as wide as a thickness of one of the PV cell layers 406, 414, and/or a gap caused by a feature such as electrical connecting wires, insulation materials and/or a dielectric but which is of a greater extent than required by the purpose of the feature, are breaks in optical coverage for the purposes of continuous coverage. In certain embodiments, any coverage gap extending the entire width or length of the solar active area is a gap in coverage for the purposes of continuous coverage.

It can be seen in FIG. 4 that the first PV cell layer 406 and the second PV cell layer 414 provide a continuous optical coverage throughout the solar active area. Continuous optical coverage that extends throughout the solar active area includes, without limitation, coverage for which the continuous portion of the coverage extends substantially the entire length and substantially the entire width of the solar active area, coverage for which the continuous portion extends for more than half of both the length and width of the solar active area, coverage for which the continuous portion exceeds 50% of the solar active area, coverage for which the continuous portion exceeds 60% of the solar active area, coverage for which the continuous portion exceeds 70% of the solar active area, coverage for which the continuous portion exceeds 80% of the solar active area, coverage for which the continuous portion exceeds 85% of the solar active area, coverage for which the continuous portion exceeds 90% of the solar active area, and/or coverage for which the continuous portion exceeds 95% of the solar active area. One of skill in the art will recognize, having the benefit of the disclosures herein, that all of the described embodiments of continuous optical coverage throughout the solar active area are achievable utilizing the first and second PV cell layer structure described herein, and each embodiment is beneficial to and/or relevant to specific embodiments of an apparatus, depending upon the application-specific parameters for a given apparatus, which application-specific parameters are varied but generally readily available to one of skill in the art contemplating a particular application. Without limitation, example application-specific parameters include the heat dissipation environment of the apparatus, the solar active area utilization and efficiency of competing products for the application, the cost of materials and manufacturing techniques for the various components of the apparatus, the selection of materials for the PV materials of the PV cell layers and the costs and efficiencies thereof, and the relative benefit of electrical generation from the apparatus including costs saved, direct financial benefit from the energy generated, and/or downstream efficiency losses.

A first bus 404 coupled to the first PV cell layer 406 and a second bus 408 coupled to the second PV cell layer 414 are depicted. The position of the busses 404, 408 at the narrower ends of the solar active area 410 is a non-limiting example. The specifics of the electrical circuits (e.g. serial, parallel, or serial-parallel) including the first and second PV cell layers 406, 414, are not depicted. In the example of FIG. 4, the busses 404, 408 are depicted as stacked to reduce the optical footprint within the solar active area 410.

The PV cell layers 406, 414 are positioned each having a number of cells having an aspect ratio, where a major axis of the cells in the first PV cell layer 406 are positioned in a first direction, and where the major axis of the cells in the second PV cell layer 414 are positioned in a second direction that is divergent from the first direction. In the embodiment of FIG. 4, the first and second directions are perpendicular to each other. The selected direction between the first and second directions may be any value, and may be determined according to a geometry of the apparatus 400, a position of an external circuit coupling, or any other criteria.

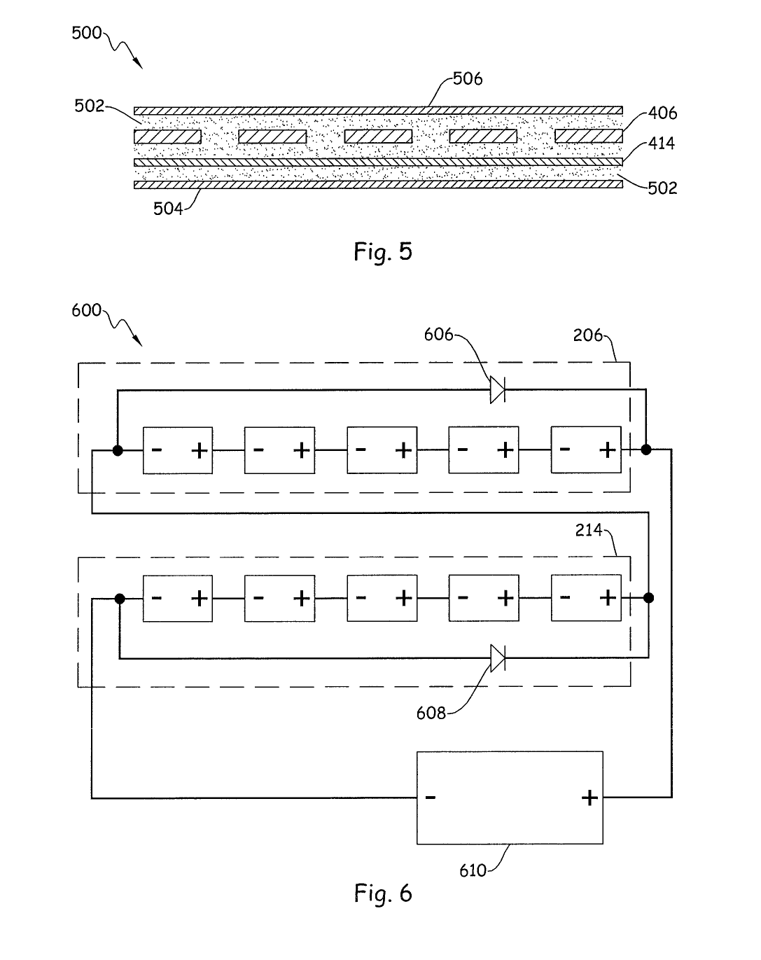

Referencing FIG. 5, an apparatus 500 is depicted in a side cross-section. The apparatus 500 is consistent with an embodiment of the apparatus 400, although the apparatuses 400, 500 may be separate embodiments. The apparatus 500 includes the first PV cell layer 406 positioned vertically above the second PV cell layer 414. The second PV cell layer 414 (e.g. reference FIG. 4) is shaped to the solar active area and is positioned vertically below the first PV cell layer 406.

The first and second PV cell layers 406, 414 are electrically isolated, separated by the encapsulant 502 which is, at least in certain embodiments, electrically insulating. Additionally or alternatively, the first and second PV cell layers 406, 414 are electrically isolated with dedicated positioned insulation materials and/or dielectric materials. In certain embodiments, the first and second PV cell layers 406, 414 are electrically isolated within the frame of the solar active area, but may be electrically connected elsewhere, for example in an external circuit, on a bus positioned outside the frame of the solar active area, or otherwise. The apparatus 500 further includes a transparent front sheet 506 that defines the solar active area, and a back sheet 504.

Referencing FIG. 6, a schematic illustration 600 depicts a first PV cell layer 206 and a second PV cell layer 214. The first and second PV cell layers 206, 214 include five (5) series PV elements each for illustration, although the arrangements of, and numbers of, the PV elements within each of the first and second PV cell layers 206, 214 may be parallel or mixed series-parallel. The first and second PV cell layers 206, 214 may include other features for a first and second PV cell layer described herein, such as begin at least partially displaced and defining a continuous optical coverage area throughout a solar active area. Such features are omitted for the purposes of clarity of the illustration 600. The first PV cell layer 206 includes a bypass diode 606, and the second PV cell layer 214 includes a second bypass diode 608 which is distinct from the first PV cell layer. The use of separate bypass diodes 606, 608 provides a different shading response for an apparatus utilizing the first and second PV cell layers 206, 214 relative to a conventional building integrated PV device. Additionally or alternatively, each PV cell layer 206, 214 may include a plurality of bypass diodes. The utilization of separate bypass diodes is a non-limiting example. In certain embodiments, a bypass diode may be configured to bypass one or more solar cells from each of the PV cell layers 206, 214. The illustration 600 depicts an electrical storage device 610 and/or load for illustrative purposes only.

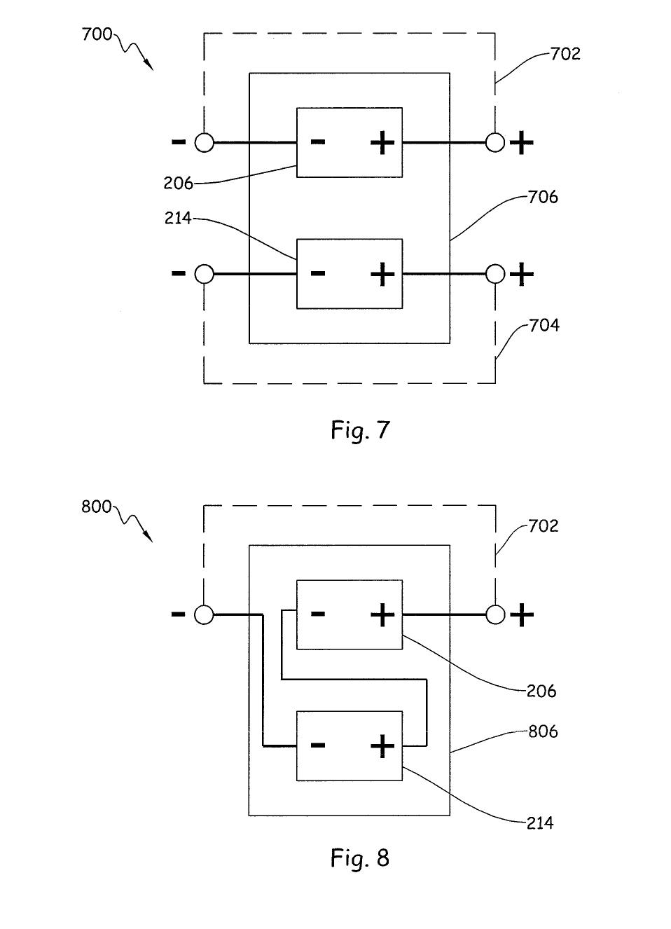

Referencing FIG. 7, an illustration 700 includes an apparatus 706 having a first PV cell layer 206 electrically coupled to an external circuit coupling 702. The apparatus 706 further includes a second PV cell layer 214 electrically coupled to a second external circuit coupling 704. The external circuit couplings 702, 704 may be any external circuit coupling known in the art, including without limitation electrical connections for a roofing shingle. The separate external circuit couplings 702, 704 provide degrees of freedom for design variation in a system including the apparatus 706, for example providing the first PV cell layer 206 with a particular electrical characteristic and the second PV cell layer 214 with a different electrical characteristic. The output provided at the external circuit couplings 702, 704 can be modified according to the surface area coverage of each of the first and second PV cell layers 206, 214 and by the electrical configuration (e.g. series, parallel, mixed series-parallel) of each of the first and second PV cell layers 206, 214.

Referencing FIG. 8, an illustration 800 includes an apparatus 806 having a first PV cell layer 206 and a second PV cell layer 214 electrically coupled to a first external circuit coupling 702. The example of the illustration 800 shows a series connection of the first and second PV cell layers 206, 214, however the connection may be parallel or mixed series-parallel.

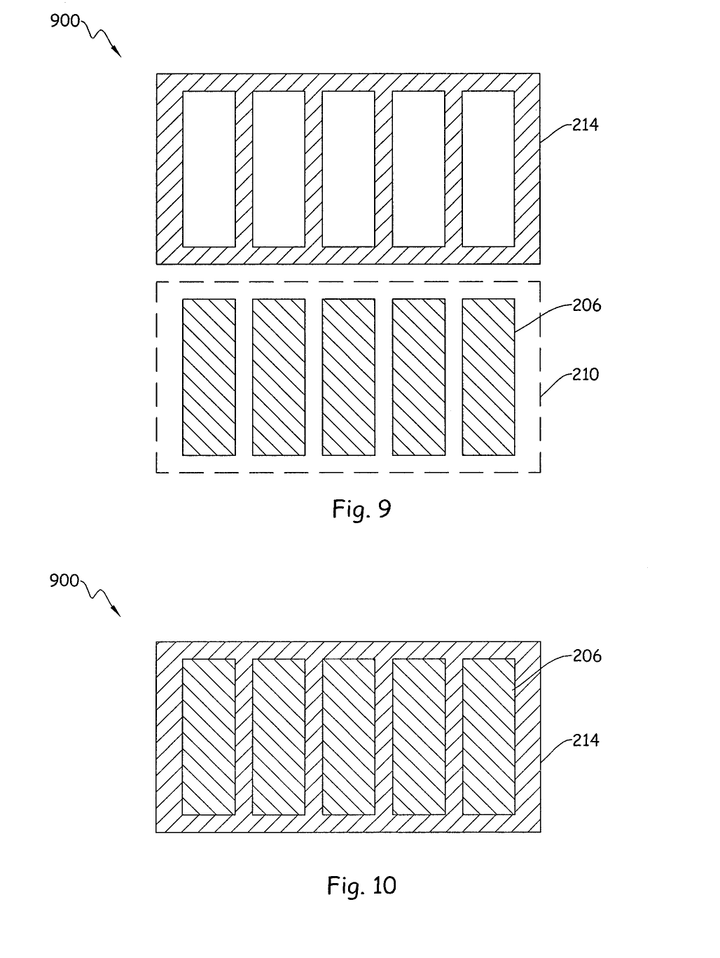

Referencing FIG. 9, an illustration 900 depicts an embodiment of a first PV cell layer 206 and a second PV cell layer 214 in an exploded view. An outline for the solar active area within the transparent front sheet 210 is shown for reference, although the transparent front sheet 210 is omitted for clarity. The second PV cell layer 214 includes a frame shaped to the solar active area less an accommodation for the first PV cell layer 206. An accommodation can include removed material shaped to expose the solar cells of the first PV cell layer 206 as shown in the illustration 900. Additionally or alternatively, the accommodation can include additional removed material to allow room for a physical component of the first PV cell layer 206, such as a bus. In certain embodiments, the accommodation includes removed material that provides a prescribed amount of exposure of the solar cells of the first PV cell layer 206 (e.g. where the second PV cell layer is the vertically higher layer). Additionally or alternatively, the accommodation may include removed material that provides a prescribed amount of exposure for the second PV cell layer 214 (e.g. where the second PV cell layer is the vertically lower layer). The term “removed material” in the sense of the present disclosure is a geometric description of the configuration of a frame shaped with accommodation, and includes objects created with the missing portions initially created, for example with a molded frame for the second PV cell layer 214.

In certain embodiments, the second PV cell layer 214 includes a substrate frame with a PV material deposited thereupon, for example a glass or stainless steel substrate with a CIGS material deposited thereupon. The second PV cell layer 214 frame may include etching, deposition gaps in material, or other features thereupon to electrically isolate portions of the “frame” and thereby create a plurality of solar cells. Additionally or alternatively, the second PV cell layer 214 may be a single electrically continuous device.

Referencing FIG. 10, the illustration 900 is depicted with the second PV cell layer 214 positioned with the first PV cell layer 206 forming a continuous optical coverage area throughout the solar active area. The first and second PV cell layers 206, 214 may be positioned in the same plane, with the first PV cell layer 206 positioned vertically higher, or with the second PV cell layer 214 positioned vertically higher.

The schematic flow descriptions which follow provide an illustrative embodiment of performing procedures for providing a PV apparatus. Operations illustrated are understood to be exemplary only, and operations may be combined or divided, and added or removed, as well as re-ordered in whole or part, unless stated explicitly to the contrary herein. Certain operations illustrated may be implemented by a computer executing a computer program product on a computer readable medium, where the computer program product comprises instructions causing the computer to execute one or more of the operations, or to issue commands to other devices to execute one or more of the operations.

Certain operations described herein include operations to interpret one or more parameters. Interpreting, as utilized herein, includes receiving values by any method known in the art, including at least receiving the value as an operator input, receiving values from a datalink or network communication, receiving an electronic signal (e.g. a voltage, frequency, current, or PWM signal) indicative of the value, receiving a software parameter indicative of the value, reading the value from a memory location on a computer readable medium, receiving the value as a run-time parameter by any means known in the art, and/or by receiving a value by which the interpreted parameter can be calculated, and/or by referencing a default value that is interpreted to be the parameter value.

An example procedure includes an operation to form a photovoltaic device. The forming includes providing a first PV cell layer that includes a first PV active material and a second PV cell layer that includes a second PV active material. The procedure further includes an operation to position the second PV cell layer at least partially displaced from the first PV cell layer. The procedure further includes an operation to interpret an external circuit description. The external circuit description is any description of a voltage and/or current requirement for one or more external circuits. The external circuit description may be a quantitative value (e.g. 6.0 V DC output), a descriptive value (e.g. series configuration), and/or a categorical description (e.g. a “Type 00038 configuration”) where the categorical description includes a predetermined value and/or a value that can be determined at runtime, e.g. through a query.

The procedure further includes an operation to electrically couple the first PV cell layer and the second PV cell layer in an electrical configuration selected in response to the external circuit description. In certain embodiments, the characteristics of each entire PV cell layer, and/or individual solar cells within each PV cell layer, are known, modeled, or determined, and compared to the external circuit description and/or parameters determined in response to the external circuit description. An electrical configuration of the first PV cell layer and/or the second PV cell layer is provided in response to the external circuit description. Example and non-limiting responses include providing the first and second PV cell layers with: an electrical configuration that matches the external circuit description, an electrical configuration that provides a closest available match to the external circuit description (wherein the closes available match may include criteria such as do not exceed voltage values, etc.), and/or a default electrical configuration (e.g. where no relevant match can be made).

The procedure further includes an operation to provide a transparent front sheet and a back sheet, and an operation to position the PV device between the front sheet and the back sheet such that the front sheet defines a solar active area, and the first and second PV cell layers define a continuous optical coverage area throughout the solar active area. The procedure further includes an operation to structurally couple the front sheet to the back sheet.

In certain embodiments, the operation to electrically couple the first PV cell layer and the second PV cell layer includes electrically coupling the PV cell layers in series to an external circuit coupling. In certain embodiments, the operation to electrically couple the first PV cell layer and the second PV cell layer includes electrically coupling the PV cell layers in parallel to an external circuit coupling. In certain embodiments, the operation to electrically couple the first PV cell layer and the second PV cell layer includes electrically coupling the first PV cell layer to a first external circuit coupling and electrically coupling the second PV cell layer to a second external circuit coupling.

Any numerical values recited in the above application include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, further including from 20 to 80, also including from 30 to 70, it is intended that values such as 15 to 85, 22 to 68, 43 to 51, 30 to 32 etc. are expressly enumerated in this disclosure. One unit is considered to be the most precise unit disclosed, such as 0.0001, 0.001, 0.01 or 0.1 as appropriate. These are only examples of what is specifically intended and all possible combinations of numerical values between the lowest value and the highest value enumerated are to be considered to be expressly stated in this disclosure in a similar manner.

Unless otherwise stated, all ranges include both endpoints and all numbers between the endpoints. The disclosures of all articles and references, including patent applications and publications, are incorporated by reference for all purposes. The use of the terms “comprising” or “including” describing combinations of elements, ingredients, components or steps herein also contemplates embodiments that consist essentially of the elements, ingredients, components or steps. The use of the articles “a” or “an,” and/or the disclosure of a single item or feature, contemplates the presence of more than one of the item or feature unless explicitly stated to the contrary.

Example embodiments of the present invention have been disclosed. A person of ordinary skill in the art will realize however, that certain modifications to the disclosed embodiments come within the teachings of this disclosure. Therefore, the following claims should be studied to determine the true scope and content of the invention.

What is claimed is:

1. An article of manufacture, comprising:
a transparent front sheet defining a solar active area, the front sheet structurally coupled to a back sheet, the front sheet and back sheet having a photo-voltaic (PV) device positioned there between, the PV device comprising:
a first PV cell layer comprising a first photovoltaically active material;
a second PV cell layer comprising a second photovoltaically active material; and
wherein the first PV cell layer and the second PV cell layer are at least partially displaced and define a continuous optical coverage area throughout the solar active area and are electrically isolated from each other in the solar active area.

2. The article according to claim 1, wherein the first photovoltaically active material and the second photovoltaically active material comprise distinct PV materials.

3. (canceled)

4. The article according to claim 1, wherein the continuous optical coverage is structured such that at least one of the first photovoltaically active material and the second photovoltaically active material is directly exposed over at least 85% of exposed facial area of the solar active area.

5. The article according to claim 1, wherein the first PV cell layer and the second PV cell layer each comprise a distinct bypass diode.

6. The article according to claim 1, further comprising an external circuit coupling, the external circuit coupling electrically coupled to the first PV cell layer and the second PV cell layer in an electrical configuration selected from the configurations consisting of: series, parallel, and series-parallel.

7. The article according to claim 1, further comprising a first external circuit coupling coupled to the first PV cell layer and a second external circuit coupling coupled to the second PV cell layer.

8. The article according to claim 1, the first PV cell layer comprising a first plurality of cells having an aspect ratio with a major axis positioned in a first direction, and the second PV cell layer comprising a second plurality of cells having an aspect ratio with a major axis positioned in a second direction, wherein the first direction is divergent from the second direction.

9. The article according to claim 8, wherein the first direction is perpendicular to the second direction.

10. The article according to claim 1, wherein the second PV cell layer comprises a frame, the frame comprising the second photovoltaically active material shaped to the solar active area less an accommodation for the first PV cell layer.

11. The article according to claim 10, wherein the first photovoltaically active material comprises crystalline silica, and wherein the second photovoltaically active material comprises copper-indium-gallium-selenide.

12. The article according to claim 1, wherein the second PV cell layer comprises the second photovoltaically active material shaped to the solar active area, and wherein the second PV cell layer is positioned vertically below the first PV cell layer.

13. The article according to claim 1, wherein a vertically upper one of the first PV cell layer and the second PV cell layer is positioned to optically screen an electrical connection assembly of the vertically lower one of the first PV cell layer and the second PV cell layer.

14. The article according to claim 1, wherein the article comprises a building integrated construction material unit.

15. A method, comprising:
forming a photovoltaic device, wherein the forming comprises providing a first photo-voltaic (PV) cell layer comprising a first photovoltaically active material and a second PV cell layer comprising a second photovoltaically active material, and positioning the second PV cell layer at least partially displaced from the first PV cell layer;
interpreting an external circuit description;
electrically coupling the first PV cell layer and the second PV cell layer in an electrical configuration selected in response to the external circuit description;
providing a transparent front sheet and a back sheet;
positioning the photovoltaic device between the front sheet and the back sheet, such that the front sheet defines a solar active area and the first PV cell layer and the second PV cell layer define a continuous optical coverage area throughout the solar active area and the first PV cell layer and the second PV cell layer are electrically isolated from each other in the solar active area; and
structurally coupling the front sheet to the back sheet.
